(19) United States
(12) Patent Application Publication
(10) Pub. No.: US 2008/0160722 A1
(43) Pub. Date: Jul. 3, 2008

(54) Method for manufacturing semiconductor device

(75) Inventor: Doo Sung Lee, Taebaek-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/999,372

(22) Filed: Dec. 4, 2007

(30) Foreign Application Priority Data
Dec. 27, 2006 (KR) 10-2006-00135743

(51) Int. Cl. H01L 21/76

(52) U.S. Cl. 438/440; 257/E21.54

(57) ABSTRACT

Disclosed is a method for manufacturing a semiconductor device. The method includes the steps of forming an insulating layer on a substrate, partially exposing the substrate by selectively etching the insulating layer, implanting ions into the exposed substrate using the etched insulating layer as an ion implantation mask, and removing the etched insulating layer from the ion-implanted substrate.

The present application claims the benefit under 35 U.S.C. §119 of Korean Patent Application No. 10-2006-0135743, filed Dec. 27, 2006, which is hereby incorporated by reference in its entirety.

### BACKGROUND

According to a related art semiconductor manufacturing method, a process of forming a CMOS image sensor includes implanting high density ions are implanted into polysilicon in a transistor region using a photoresist layer as a mask. FIGS. 1(a) to 4(b) are sectional views illustrating the problems according to the related art.

As shown in FIG. 1(a), a predetermined photoresist layer pattern 20 is formed on a substrate 10. Then, a high density ion implantation process is performed using the photoresist layer pattern 20 as a mask. The ion implantation is performed with ion density of 10¹⁵ ions/cm² or above as shown in FIG. 1(b). As shown in FIG. 2(a), the surface of the photoresist layer pattern 20 becomes carbonized as a result. The photoresist layer pattern 20 includes a polymer containing carbon and hydrogen. The high temperature ion implantation breaks down the polymer molecules in the photoresist causing the release of hydrogen and the carbonization of the exterior of the photoresist. Additionally, hydrogen within the photoresist layer pattern 20 is escapes to outside during the high density ion implantation process as shown in FIG. 2(b).

As shown in FIGS. 3(a) and 3(b), a popping phenomenon occurs, that is, the carbonized part is broken due to the high density ion implantation and broken pieces “pop” from the surface of the photoresist layer pattern 20 onto the substrate 10.

Further, the carbonized residue C masks a part of the substrate during a subsequent etching step. A block (or defect) B formed when the subsequent etching process is performed using a second photoresist layer 30, as shown in FIG. 4(a). A resulting irregular etching pattern is formed, as shown in FIG. 4(a).

The prevalence of the popping phenomenon and the resultant defects (e.g., block B) depend on the photoresist used and the implant dose. The incidence of defects resulting from the related art method can be as high as about 10⁴ defects per 200 mm wafer.

### BRIEF SUMMARY

Accordingly, embodiments of the present invention concern a method for manufacturing a semiconductor device that substantially obviates one or more problems due to the limitations and disadvantages of the related art.

One embodiment provides a method for manufacturing a semiconductor device, which can prevent the popping phenomenon of a photoresist layer in a semiconductor device, such as a CIS. Additional advantages, objects, and features of the invention will be set forth in part in the description which follows and in part will become apparent to those having skill in the art upon examination of the following or which can be learned from practice of the invention. The objectives and other advantages of the invention can be realized and attained by the structure particularly pointed out in the written description and claims hereof as well as the appended drawings.

To achieve these objects and other advantages in accordance with the purpose of the present invention, as embodied and broadly described herein, there is provided a method for manufacturing a semiconductor device, the method comprising the steps of: forming an insulating layer on a substrate; partially exposing the substrate by selectively etching the insulating layer; implanting ions into the exposed substrate using the etched insulating layer as an ion implantation mask; and removing the etched insulating layer from the ion-implanted substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1(a) provides a cross-sectional view of a related art semiconductor device (e.g., a CIS) with a photoresist 20 formed over a semiconductor substrate 10;

FIG. 1(b) provides a cross-sectional view of a related art semiconductor device (e.g., a CIS) wherein ions are implanted into a semiconductor substrate 10 and a photoresist 20;

FIG. 2(a) provides a cross-sectional view of a related art semiconductor device (e.g., a CIS) substrate 10 and carbonized photoresist 20 after the ion implantation step;

FIG. 2(b) provides a cross-sectional view of a related art semiconductor device (e.g., a CIS) substrate 10 after the ion implantation step, including the migration of H⁺ to the exterior of photoresist 20;

FIG. 3(a) provides a cross-sectional view of a related art semiconductor device (e.g., a CIS) substrate 10 after the ion implantation step, demonstrating the damage to the photoresist 20 caused by the popping phenomenon;

FIG. 3(b) provides a cross-sectional view of a related art semiconductor device (e.g., a CIS) substrate 10 after the ion implantation, demonstrating the popping phenomenon and carbonized fragment C on an area of the substrate 10 adjacent to photoresist 20;

FIG. 4(a) provides a cross-sectional view of a related art semiconductor device (e.g., a CIS) substrate 10, as shown in 3(b), wherein the substrate 10 is masked in a subsequent etching step;

FIG. 4(b) provides a cross-sectional view of a related art semiconductor device (e.g., a CIS) substrate 10, as shown in FIG. 4(a), after the substrate 10 is etched with a carbonized “popped” fragment of the photoresist 20 thereover, resulting in a block B in the surface of substrate 10;

FIG. 5 provides a cross-sectional view of a semiconductor device (e.g., a CIS) according to the embodiments of the invention, wherein an insulating layer 120 is formed over the substrate 110 in both a cell area and a peripheral area of a wafer.

FIG. 6 provides a cross-sectional view of a semiconductor device (e.g., a CIS) according to the embodiments of the invention, wherein a photoresist layer (P/R) is formed over the insulating layer 120 in both the peripheral area of a wafer.

FIG. 7 provides a cross-sectional view of a semiconductor device (e.g., a CIS) according to the embodiments of the invention, wherein an insulating layer 120 has been removed in the cell area of the wafer.

FIG. 8 provides a cross-sectional view of a semiconductor device (e.g., a CIS) according to the embodiments of the invention, wherein ions are implanted into substrate 110 in the cell area of the wafer, using the etched insulating layer 120 as a mask.

FIG. 9 provides a cross-sectional view of a semiconductor device (e.g., a CIS) according to the embodiments of the invention, wherein the etched insulating layer 120 has been removed from substrate 110 in the peripheral area of the wafer.

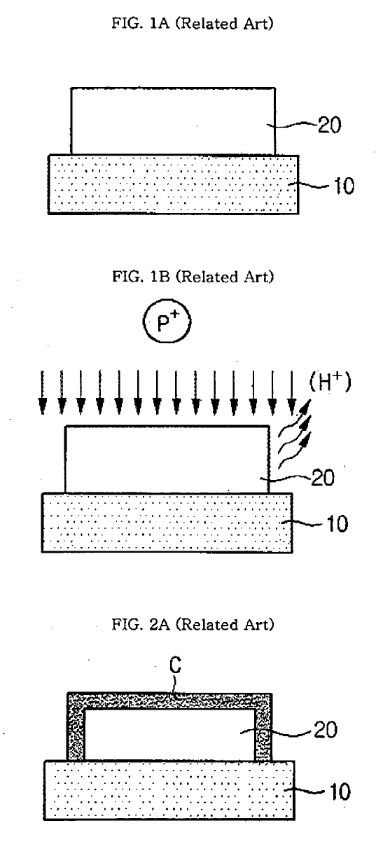

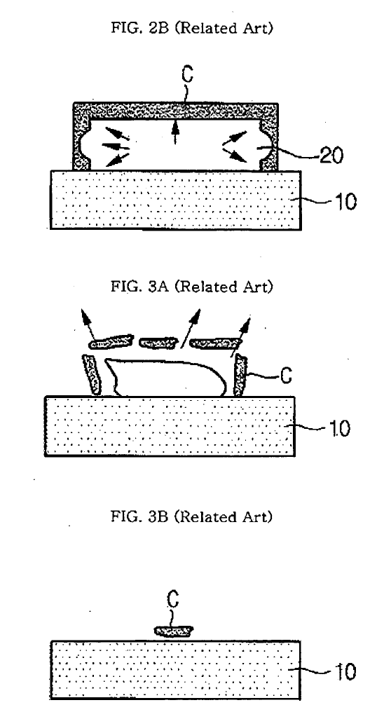

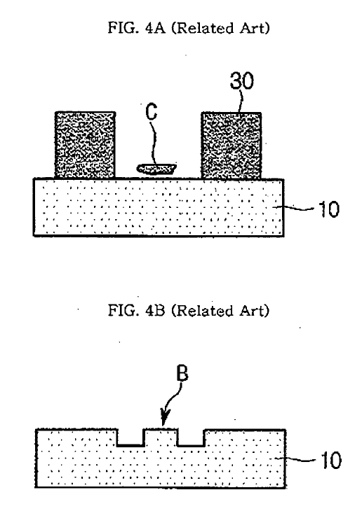

### DETAILED DESCRIPTION OF THE EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

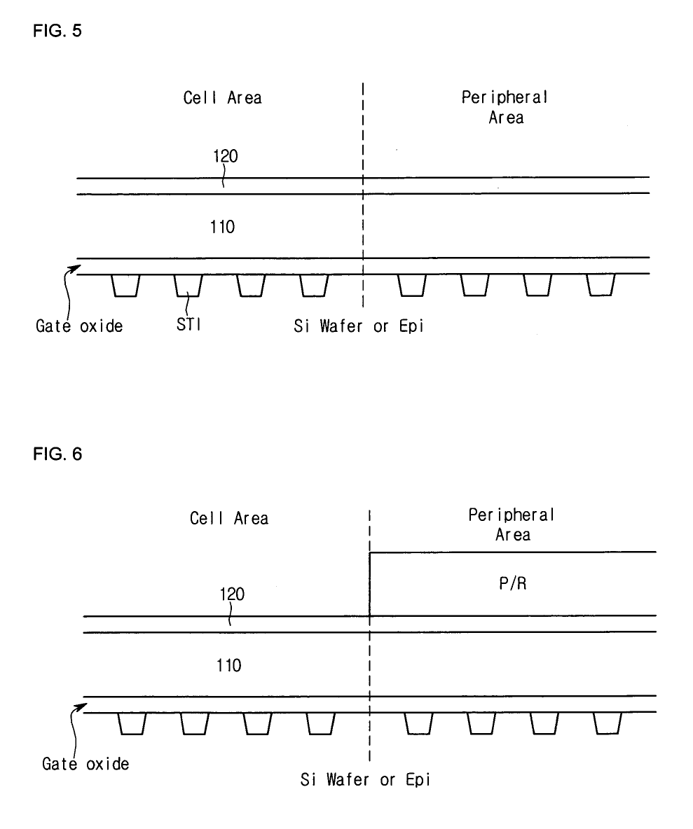

FIGS. 5 to 9 are sectional views sequentially illustrating the procedure for manufacturing a semiconductor device according to embodiments of the present invention. First, an insulating layer 120 is formed on a substrate 110 as shown in FIG. 5. Insulating layer 120 can be formed from conventional materials (e.g., silicon nitride, silicon dioxide, silicon oxynitride). The substrate 110 may include a substrate of a MOS transistor, a substrate of a CMOS image sensor, a substrate of an LED or another type of semiconductor device. In one embodiment, the substrate includes a single crystal silicon wafer (which may have an epitaxial silicon layer formed thereon) with shallow trench isolation (STI) structures therein, a gate oxide on the active regions of the wafer, and a polysilicon layer 110 on its upper surface.

In one embodiment, the insulating layer 120 may later serve as an ion implantation mask. In this particular embodiment the insulating layer is preferably silicon nitride. Other materials (e.g., oxide) may allow damage to the underlying substrate 110 during an ion implantation step. For instance, oxygen atoms from an oxide layer may be added to the underlying substrate by oxygen recoiling during the ion implantation. Consequently, an undesired reduction of the vertical dimension of the polysilicon substrate 110 may occur during a subsequent etching step.

As shown in FIG. 6, a photoresist layer pattern 130 is formed on the insulating layer 120 by conventional photoresist deposition and photolithography (e.g., selective irradiation through a mask and subsequent development). The photoresist layer pattern 130 is formed over a part of the insulating layer 120 that is in a peripheral area of the die (e.g., the CIS device, LED driver, or the like). The insulating layer 120 remains exposed in a cell area or a logic area of the die (e.g., a pixel region of a CIS die).

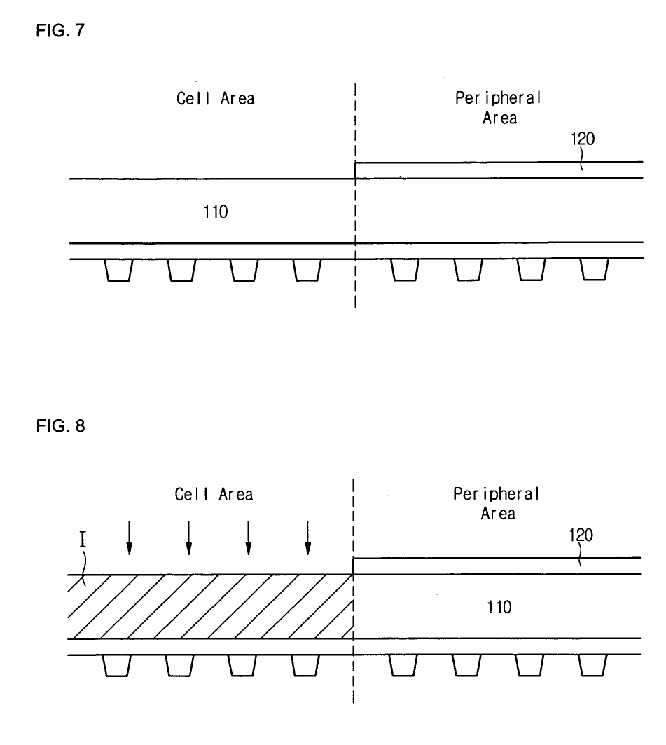

Next, as shown in FIG. 7, the exposed part of the insulating layer 120 is etched (preferably by dry and/or anisotropic etching) using the photoresist layer pattern 130 as an etching mask, thereby partially exposing the substrate 110 in the cell area the logic area, or the pixel region of the die. Accordingly, the insulating layer 120 is patterned as an ion implantation mask (e.g., a hard mask). According to one embodiment, the insulating layer 120 (i.e., the exposed nitride layer) can be removed without causing damage to the polysilicon layer 110. Thereafter, as shown in FIG. 7, the photoresist layer pattern 130 is removed from the etched insulating layer 120 in the peripheral area of the wafer.

As shown in FIG. 8, high density ions (e.g., phosphorus ions [P⁺]) are implanted into the exposed substrate 110 using the etched insulating layer 120 as an ion implantation mask (e.g., a hard mask), thereby forming an ion implantation region I in the cell area, logic area or pixel region of the die. The ion implantation process can be performed with an ion density or dose of about 10¹⁵ ions/cm² or more. In one embodiment, the exposed part of the substrate 110 may correspond to the polysilicon layer for formation of gates in a transistor region of a CMOS image sensor (e.g., a gate-forming layer).

According to the related art, when the ion implantation process is performed with an ion density of about 10¹⁵ ions/cm² or more using a photoresist layer pattern as a mask, a popping phenomenon may occur. Specifically, a carbonized portion of the photoresist layer is broken due to the high density ion implantation and broken pieces of the photoresist may “pop” from the surface of the photoresist layer pattern onto the substrate to be etched.

However, according to embodiments of the method, polysilicon is deposited on a semiconductor device such as CIS, and an ion implantation hard mask is formed using an insulator (e.g., a nitride layer), instead of the photoresist layer, thereby preventing the popping phenomenon of the photoresist layer.

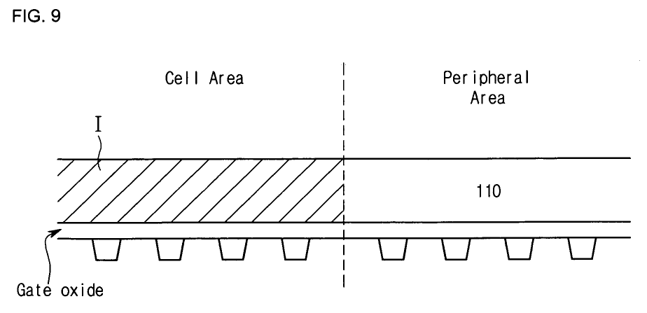

As shown in FIG. 9, the etched insulating layer 120 is removed from the ion-implanted substrate 110 (e.g., by wet etching, such as immersion in warm or hot aqueous phosphoric acid). Subsequently, substrate 110 can be patterned to form device structures (e.g., polysilicon layer 110 can be patterned to form transistor gates).

According to embodiments of the invention, the insulating layer pattern (e.g., a nitride layer) can be removed without causing damage to the polysilicon substrate, so that the insulating layer pattern does not exert a bad influence upon the characteristics of the semiconductor device. Irregularities or defects in subsequent etching or patterning steps (e.g., the formation of gate structures) can be avoided. Thus, the negative impact on device characteristics that results from a popping phenomenon can also be avoided.

According to exemplary embodiments as described above, polysilicon is deposited over a semiconductor device, such as a CIS, and an ion implantation mask is formed using an insulator such as a nitride layer, instead of a photoresist layer, thereby avoiding the popping phenomenon of the related art method. The present method reduces an incidence of defects to about 10 to 100 defects per 200 mm wafer. This is a significant reduction from the 10⁴ defects associated with the related art method.

Further, according to the example embodiments, the insulating layer pattern (e.g., nitride layer) can be removed without causing damage to the polysilicon, so that the insulating layer pattern does not negatively impact the semiconductor device characteristics.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art. It is intended that the present invention covers the modifications and variations of this invention provided they come within the scope of the appended claims and their equivalents.

1. A method for manufacturing a semiconductor device comprising the steps of:
forming an insulating layer on a substrate;
partially exposing the substrate by selectively etching the insulating layer;
implanting ions into the exposed substrate using the etched insulating layer as an ion implantation mask; and
removing the etched insulating layer from the ion-implanted substrate.

2. The method of claim 1, wherein the step of partially exposing the substrate comprises:
forming a photoresist layer pattern on the insulating layer; and
partially exposing the substrate by etching an exposed part of the insulating layer using the photoresist layer pattern as an etching mask.

3. The method of claim 2, further comprising
removing the photoresist layer pattern from the etched insulating layer

4. The method of in claim 1, wherein the insulating layer comprises a nitride layer.

5. The method of claim 3, wherein the insulating layer comprises a nitride layer.

6. The method of claim 1, wherein the ions are implanted at a density of more than 10¹⁵ ions/cm².

7. The method of in claim 3, wherein the ions are implanted at a density of more than 10¹⁵ ions/cm².

8. The method of claim 1, wherein an exposed part of the substrate comprises a transistor region of a CMOS image sensor.

9. The method of claim 1, wherein removing the photoresist layer pattern comprises removing substantially all of the photoresist from the surface of the etched insulating layer.

10. The method of claim 1, wherein an exposed part of the substrate is in a cell area of the semiconductor device.

11. The method of claim 1, wherein an area of the substrate covered by the etched insulating layer is in a peripheral area of the semiconductor device.

12. The method of claim 1, wherein selectively etching the insulating layer comprises dry etching the insulating layer.

13. The method of claim 1, wherein removing the etched insulating layer comprises wet etching the etched insulating layer.

14. The method of claim 1, wherein the substrate comprises a polysilicon layer at an upper surface thereof.

15. The method of claim 1, further comprising patterning the substrate to form gate structures after removing the etched insulating layer.

16. The method of claim 4, wherein the insulating layer comprises a silicon nitride layer.

17. The method of claim 1, wherein the substrate comprises:
a semiconductor wafer;
shallow trench isolation structures in the semiconductor wafer;
a gate oxide layer on or over the semiconductor wafer; and
a polysilicon layer on the gate oxide layer.

18. The method of claim 17, wherein the ions are implanted into the polysilicon layer.

19. The method of claim 18, further comprising patterning the polysilicon layer to form gate structures in a transistor region of a CMOS image sensor after removing the etched insulating layer.

20. The method of claim 1, wherein implanting ions comprises implanting phosphorus ions.
